(19) United States
(12) Patent Application Publication
(10) Pub. No.: US 2023/0387162 A1
(43) Pub. Date: Nov. 30, 2023

(54) PHOTOSENSITIVE ASSEMBLY, IMAGING SYSTEM, AND OPTICAL ELECTRONIC DEVICE

(71) Applicant: Shphotonics Ltd, Suzhou (CN)

(72) Inventors: Lei SUN, Suzhou (CN); Bing QIU, Suzhou (CN)

(21) Appl. No.: 18/321,137

(22) Filed: May 22, 2023

(30) Foreign Application Priority Data
May 25, 2022 (CN) 202221391476.9

(51) Int. Cl. H01L 27/146; G02B 5/20; G02B 1/00; H04N 25/13

(52) U.S. Cl. CPC H01L 27/14625; H01L 27/14621; G02B 5/201; G02B 1/002; H04N 25/134; G02B 27/288

(57) ABSTRACT

A photosensitive assembly includes a photosensitive element including a plurality of pixels arranged in an array, the plurality of pixels including two groups of pixels configured to respectively sense incident light of different properties; a filter element including at least one of a color filter including a plurality of color filter units arranged in one-to-one correspondence with the plurality of pixels, the plurality of color filter units including two groups of color filter units corresponding to the two groups of pixels, respectively, and each of the two groups of color filter units having a light-passing wavelength band corresponding to a wavelength band sensed by a corresponding one of the two groups of pixels, a polarization filter, or an aperture; and a metasurface light-guiding element configured to guide the incident light of different properties to respective ones of the two groups of pixels.

### CROSS-REFERENCE TO RELATED APPLICATION

This application claims priority to Chinese Application No. 202221391476.9, filed on May 25, 2022, the entire content of which is incorporated herein by reference.

### TECHNICAL FIELD

The present disclosure relates to optical imaging and, in particular, to a photosensitive assembly, an imaging system, and an optical electronic device.

### BACKGROUND

In related technologies, imaging systems such as mobile phones, augmented reality devices, and virtual reality devices often have problems of low light transmission efficiency and low signal-to-noise ratio, which limits their use in weak light and low reflectivity scenarios. Thus, improving image quality of the imaging systems in these scenarios is a highly desirable and challenging technical problem.

### SUMMARY

One aspect of the present disclosure provides a photosensitive assembly. The photosensitive assembly includes a photosensitive element, a filter element, and a metasurface light-guiding element. The photosensitive element includes a plurality of pixels arranged in an array and including two groups of pixels configured to respectively sense incident light of different properties, which include incident light of different wavelength bands or incident light of different polarization directions. The filter element includes at least one of a color filter including a plurality of color filter units arranged in one-to-one correspondence with the plurality of pixels, a polarization filter, or an aperture including a plurality of light-transmission regions arranged in one-to-one correspondence with the plurality of pixels. The plurality of color filter units includes two groups of color filter units corresponding to the two groups of pixels, respectively, and each of the two groups of color filter units has a light-passing wavelength band corresponding to a wavelength band sensed by a corresponding one of the two groups of pixels. The metasurface light-guiding element is configured to guide the incident light of different properties to respective ones of the two groups of pixels.

Another aspect of the present disclosure provides an imaging system. The imaging system includes a photosensitive assembly. The photosensitive assembly includes a photosensitive element, a filter element, and a metasurface light-guiding element. The photosensitive element includes a plurality of pixels arranged in an array and including two groups of pixels configured to respectively sense incident light of different properties, which include incident light of different wavelength bands or incident light of different polarization directions. The filter element includes at least one of a color filter including a plurality of color filter units arranged in one-to-one correspondence with the plurality of pixels, a polarization filter, or an aperture including a plurality of light-transmission regions arranged in one-to-one correspondence with the plurality of pixels. The plurality of color filter units includes two groups of color filter units corresponding to the two groups of pixels, respectively, and each of the two groups of color filter units has a light-passing wavelength band corresponding to a wavelength band sensed by a corresponding one of the two groups of pixels. The metasurface light-guiding element is configured to guide the incident light of different properties to respective ones of the two groups of pixels.

Another aspect of the present disclosure includes an optical electronic device. The optical electronic device includes an imaging system, The imaging system includes a photosensitive assembly. The photosensitive assembly includes a photosensitive element, a filter element, and a metasurface light-guiding element. The photosensitive element includes a plurality of pixels arranged in an array and including two groups of pixels configured to respectively sense incident light of different properties, which include incident light of different wavelength bands or incident light of different polarization directions. The filter element includes at least one of a color filter including a plurality of color filter units arranged in one-to-one correspondence with the plurality of pixels, a polarization filter, or an aperture including a plurality of light-transmission regions arranged in one-to-one correspondence with the plurality of pixels. The plurality of color filter units includes two groups of color filter units corresponding to the two groups of pixels, respectively, and each of the two groups of color filter units has a light-passing wavelength band corresponding to a wavelength band sensed by a corresponding one of the two groups of pixels. The metasurface light-guiding element is configured to guide the incident light of different properties to respective ones of the two groups of pixels.

### BRIEF DESCRIPTION OF THE DRAWINGS

To more clearly illustrate the technical solution of the present disclosure, the accompanying drawings used in the description of the disclosed embodiments are briefly described below. The drawings described below are merely some embodiments of the present disclosure. Other drawings may be derived from such drawings by a person with ordinary skill in the art without creative efforts and may be encompassed in the present disclosure.

FIGS. 1-4 are schematic diagrams of various exemplary photosensitive assemblies according to some embodiments of the present disclosure; and

FIG. 5 is a schematic diagram of an exemplary imaging system according to some embodiments of the present disclosure.

### NUMERAL LABELS IN THE DRAWINGS INCLUDE

100 photosensitive assembly
110 photosensitive element
111 pixel
120 filter element
121 color filter
1210 color filter unit
130 metasurface light-guiding element
131 substrate
132 nano-structure unit
140 polarization filter
150 aperture
151 light-transmission region
160 optical focus element
200 imaging system

### DETAILED DESCRIPTION OF THE EMBODIMENTS

In the following, some example embodiments are described. As those skilled in the art would recognize, the described embodiments can be modified in various different manners, all without departing from the spirit or scope of the present disclosure. Accordingly, the drawings and descriptions are illustrative in nature and not limiting.

In the present disclosure, terms such as “first,” “second,” and “third” can be used to describe various elements, components, regions, layers, and/or parts. However, these elements, components, regions, layers, and/or parts should not be limited by these terms. These terms are only used to distinguish one element, component, region, layer, or part from another element, component, region, layer, or layer. Therefore, a first element, component, region, layer, or part discussed below can also be referred to as a second element, component, region, layer, or part, which does not constitute a departure from the teachings of the present disclosure.

A term specifying a relative spatial relationship, such as “below,” “beneath,” “lower,” “under,” “above,” or “higher,” can be used in the disclosure to describe the relationship of one or more elements or features relative to other one or more elements or features as illustrated in the drawings. These relative spatial terms are intended to also encompass different orientations of the device in use or operation in addition to the orientation shown in the drawings. For example, if the device in the a drawing is turned over, an element described as “beneath,” “below,” or “under” another element or feature would then be “above” the other element or feature. Therefore, an example term such as “beneath” or “under” can encompass both above and below. Further, a term such as “before,” “in front of,” “after,” or “subsequently” can similarly be used, for example, to indicate the order in which light passes through the elements. A device can be oriented otherwise (e.g., being rotated by 90 degrees or being at another orientation) while the relative spatial terms used herein still apply. In addition, when a layer is referred to as being “between” two layers, it can be the only layer between the two layers, or there can be one or more intervening layers.

Terminology used in the disclosure is for the purpose of describing the embodiments only and is not intended to limit the present disclosure. As used herein, the terms “a,” “an,” and “the” in the singular form are intended to also include the plural form, unless the context clearly indicates otherwise. Terms such as “comprising” and/or “including” specify the presence of stated features, entities, steps, operations, elements, and/or parts, but do not exclude the existence or addition of one or more other features, integers, steps, operations, elements, parts, and/or combinations thereof. As used herein, the term “and/or” includes any and all combinations of one or more of the listed items. The phrases “at least one of A and B” and “at least one of A or B” mean only A, only B, or both A and B.

When an element or layer is referred to as being “on,” “connected to,” “coupled to,” or “adjacent to” another element or layer, the element or layer can be directly on, directly connected to, directly coupled to, or directly adjacent to the other element or layer, or there can be one or more intervening elements or layers. In contrast, when an element or layer is referred to as being “directly on,” “directly connected to,” “directly coupled to,” or “directly adjacent to” another element or layer, then there is no intervening element or layer. “On” or “directly on” should not be interpreted as requiring that one layer completely covers the underlying layer.

In the disclosure, description is made with reference to schematic illustrations of example embodiments (and intermediate structures). As such, changes of the illustrated shapes, for example, as a result of fabrication techniques and/or tolerances, can be expected. Thus, embodiments of the present disclosure should not be interpreted as being limited to the specific shapes of regions illustrated in the drawings, but are to include deviations in shapes that result, for example, from fabrication. Therefore, the regions illustrated in the drawings are schematic and their shapes are not intended to illustrate the actual shapes of the regions of the device and are not intended to limit the scope of the present disclosure.

Unless otherwise defined, all terms (including technical and scientific terms) used herein have the same meaning as commonly understood by those of ordinary skill in the art to which this disclosure belongs. Terms such as those defined in commonly used dictionaries should be interpreted to have meanings consistent with their meanings in the relevant field and/or in the context of this disclosure, unless expressly defined otherwise herein.

As used herein, the term “substrate” can refer to the substrate of a diced wafer, or the substrate of an un-diced wafer. Similarly, the terms “chip” and “die” can be used interchangeably, unless such interchange would cause conflict. The term “layer” can include a thin film, and should not be interpreted to indicate a vertical or horizontal thickness, unless otherwise specified.

In related technologies, imaging systems such as mobile phones, augmented reality devices, and virtual reality devices often have problems of low light transmission efficiency and low signal-to-noise ratio (SNR), which limits their use in weak light and low reflectivity scenarios. The SNR is a ratio of signal to noise in an electronic device or electronic system.

The present disclosure provided a photosensitive assembly, an imaging system, and an optical electronic device to improve the light transmission efficiency and the SNR of the imaging system, thereby improving imaging quality.

In some embodiments, the photosensitive assembly includes a photosensitive element, at least one filter element, and a metasurface light-guiding element that are stacked one on another. The photosensitive element includes a plurality of pixels arranged in an array. The plurality of pixels include at least two groups of pixels. The at least two groups of pixels are configured to respectively sense incident light of different properties. For example, the property of the incident light includes a wavelength band or a polarization direction. The at least one filter element includes at least one of a color filter, a polarization filter, or an aperture. The color filter includes a plurality of color filter units that are arranged in one-to-one correspondence with the plurality of pixels. The plurality of color filter units include at least two groups of color filter units corresponding to the at least two groups of pixels, respectively. Each group of color filter units has a light-passing wavelength band corresponding to a wavelength band sensed by a corresponding group of pixels in the at least two groups of pixels. The aperture includes a plurality of light-transmission regions corresponding to the plurality of pixels. The metasurface light-guiding element is configured to guide or direct the incident light of different properties to respective group of pixels in the at least two groups of pixels.

The metasurface light-guiding element guides the incident light, such that the incident light of different properties (such as the incident light of different wavelength bands or the incident light of different polarization directions) is directed to the corresponding pixels in the plurality of pixels. The at least one filter element (such as any one of color filter, polarization filter, or aperture) has a filtering effect on stray light, which improves the light transmission efficiency and the SNR of the imaging system. The improvement of the light transmission efficiency and the SNR of the imaging system can significantly improve the imaging quality.

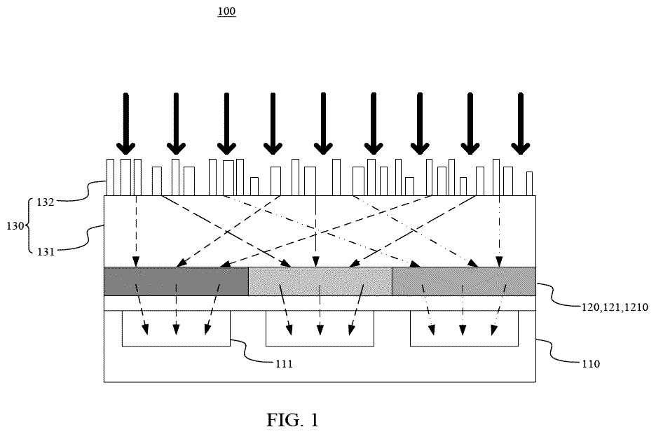

FIGS. 1-4 are schematic diagrams of various exemplary photosensitive assemblies according to some embodiments of the present disclosure. In some embodiments, as shown in FIG. 1, the photosensitive assembly 100 includes a photosensitive element 110, at least one filter element 120, and a metasurface light-guiding element 130 that are stacked one on top of another. The photosensitive element 110 includes a plurality of pixels 111 arranged in an array. The at least one filter element 120 includes a color filter 121. The color filter 121 includes a plurality of color filter units 1210 corresponding to the plurality of pixels 111. The plurality of color filter units 1210 have at least two light-pass wavelength bands corresponding to different colors. The metasurface light-guiding element 130 is configured to guide the incident light of different wavelength bands to the color filter units 1210 corresponding to the light-passing wavelength band, and then to the corresponding pixels 111.

The photosensitive element, namely an image sensor, is a device that converts an optical image into an electronic signal. The photosensitive element is widely used in digital cameras and other optical electronic devices. In some embodiments, the photosensitive element is a complementary metal-oxide-semiconductor (CMOS) photosensitive element.

The CMOS photosensitive element achieves its basic functions mainly though silicon and germanium semiconductors and transistors. The CMOS photosensitive element may also be made of III-V materials, which have the advantages of high level of integration, low power consumption, fast speeds, and low cost. The CMOS photosensitive element is widely used in imaging systems of mobile phones, augmented reality devices, virtual reality devices, etc. In some other embodiments, the photosensitive element may also be a charge-coupled device (CCD) photosensitive element, which is not specifically limited in the present disclosure.

In some embodiments, the photosensitive assembly 100 may include one or more filter elements 120. The one or more filter elements 120 filter light waves by selecting appropriate materials and structural designs. The one or more filter elements 120 may include a color filter 121, and the color filter 121 includes a plurality of color filter units 1210 arranged in one-to-one correspondence with the plurality of pixels 111. The plurality of color filter units 1210 have at least two light-passing bands corresponding to different colors. For example, among the plurality of color filter units 1210, some color filter units 1210 correspond to a light-passing band of red light, thereby only allowing red light to pass through. Some other color filter units 1210 correspond to a light-passing band of green light, thereby only allowing green light pass though. Some other color filter units 1210 correspond to a light-passing band of blue light, thereby only allowing blue light to pass through. In some embodiments, the plurality of color filter units 1210 may also include only two light-passing bands, corresponding to two color bands, for example, red light and green light, respectively.

A metasurface refers to an artificial two-dimensional material whose basic structural units are smaller than the operating light wavelengths and are usually on the order of nanometers. The metasurface element may facilitate flexible and effective control of electromagnetic wave polarization, amplitude, phase, propagation mode, and other characteristics. The metasurface element is ultra-light and ultra-thin. Compared with conventional optical components, the metasurface elements have the advantages of excellent optical performance, small size, and high level of integration.

As shown in FIG. 1, the metasurface light-guiding element 130 includes a substrate 131 used as a base for fabrication and a plurality of nano-structure units 132 disposed on one side of the substrate 131. By properly designing the plurality of nano-structure units 132, precise deflection of light may be achieved, such that incident light of different wavelength bands may be guided to corresponding color filter units 1210 having respective light-passing bands. That is, the incident light of different wavelength bands may be guided to corresponding pixels 111. For example, the red light in the incident light is guided to the color filter unit 1210 that only allows the red light to pass through, the green light in the incident light is guided to the color filter unit 1210 that only allows the green light to pass through, and the blue light in the incident light is guided to the color filter units 1210 that only allows the blue light to pass through.

The metasurface light-guiding element 130 guides the incident light, such that the incident light of different wavelength bands is guided to the color filter unit 1210 corresponding to the light-passing band. For example, the red light is guided to the color filter unit 1210 corresponding to the red light-passing band, the green light is guided to the color filter unit 1210 corresponding to the green light-passing band, and the blue light is guided to the color filter unit 1210 corresponding to the blue light-passing band. Thus, reflection and absorption of light by the plurality of color filter units 1210 are substantially reduced, and the light transmission efficiency of the imaging system is improved. In addition, the color filter 121 also has a filtering effect on stray light, such that the SNR of the imaging system can be improved. The improvement of the light transmission efficiency and the SNR of the imaging system substantially improves the imaging quality.

In some embodiments, the at least two groups of pixels 111 of the photosensitive element 110 are used to respectively sense light corresponding to different polarization directions. The metasurface light-guiding element 130 is configured to guide the incident light corresponding to different polarization directions to respective pixels 111.

As shown in FIG. 1, in some embodiments, the color filter 121 may be a dyed filter, including light blockers of multiple colors (for example, including red light blocker, green light blocker, and blue light blocker). Each light blocker corresponds to a color filter unit 1210.

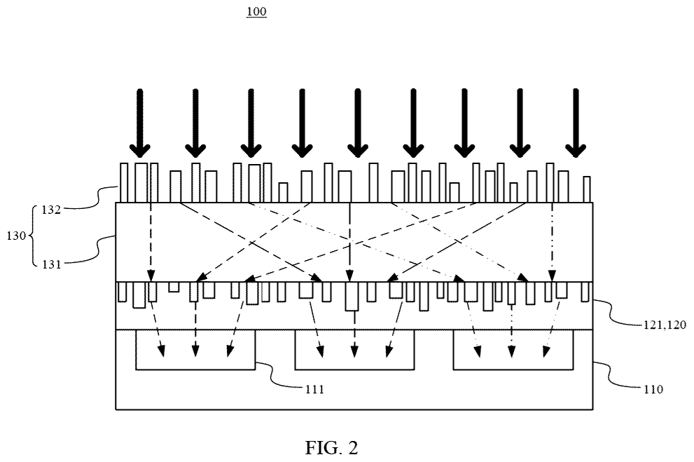

In some embodiments, as shown in FIG. 2, the color filter 121 is a metasurface element. Through the proper design of the nano-structure units of the metasurface element, stray light may be filtered out while light of the corresponding wavelength band is allowed to pass through.

In some embodiments, the color filter 121 may be a diffraction grating element or a coated grating filter, and the effect of filtering out the stray light may also be obtained through proper design of materials and structures.

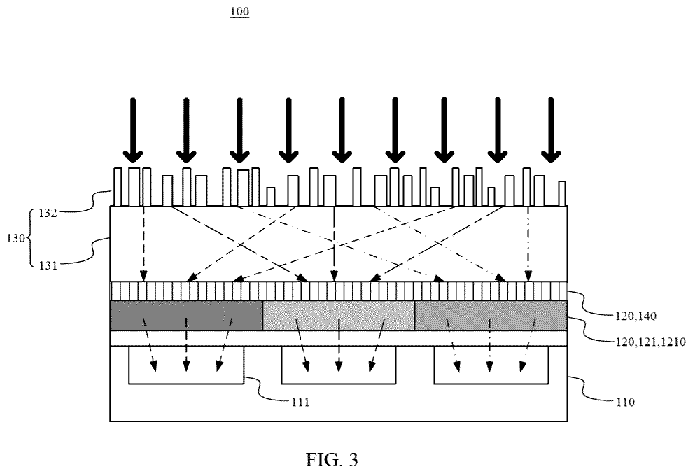

In some embodiments, as shown in FIG. 3, the photosensitive assembly 100 includes a plurality of filter elements 120. The plurality of filter elements 120 includes a color filter 121 and a polarization filter 140. The polarization filter 140 is located between the color filter 121 and the metasurface light-guiding element 130. The polarization filter 140 may filter out polarized stray light, thereby further improving the SNR of the imaging system. In some embodiments, the polarization filter 140 may also be located between the color filter 121 and the photosensitive element 110. In some embodiments, the polarization filter 140 may also be integrated with the color filter 121 to form an integrated component.

The polarization filter 140 may be a metal linear polarizer. In addition, the polarization filter 140 may also be a metasurface element, a diffraction grating element, or a coated grating filter. Through proper design of materials and structures, the effect of filtering out the polarized stray light may also be obtained, and the present disclosure is not limited thereto.

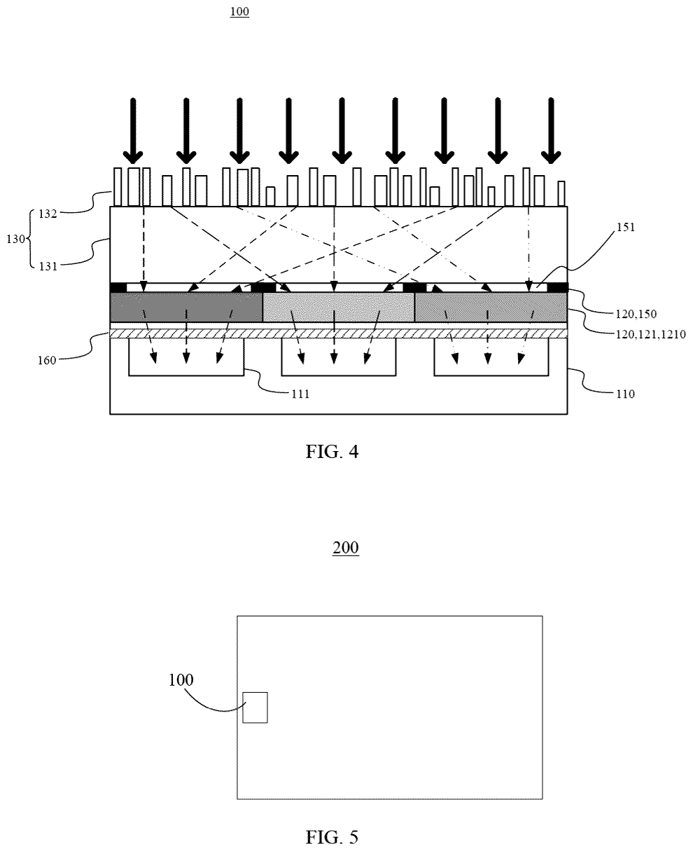

In some embodiments, as shown in FIG. 4, the photosensitive assembly 100 includes a plurality of filter elements 120. The plurality of filter elements 120 include a color filter 121 and an aperture 150. The aperture 150 is located between the color filter 121 and the metasurface light-guiding element 130, and includes a plurality of light-transmission regions 151 corresponding to the plurality of pixels 111. The aperture 150 may filter out the stray light, thereby further improving the SNR of the imaging system. In some embodiments, the aperture 150 may also be located between the color filter 121 and the photosensitive element 110. In addition, in some embodiments, the aperture 150 may also be integrated with the color filter 121 to form an integrated component.

In the embodiments of the present disclosure, a functional design of the metasurface light-guiding element 130 is not limited to deflecting and guiding light of different wavelength bands. In some embodiments, through proper design of the plurality of nano-structure units 132, it is also possible to achieve, for example, at least one of effects such as convergence, divergence, chromatic aberration adjustment, or polarization, etc., such that the imaging system can adapt to diverse optical design requirements.

In some embodiments, as shown in FIG. 1, the at least one filter element 120 and the metasurface light-guiding element 130 may be integrated on the same substrate 131. For example, the plurality of nano-structure units 132 is formed on one side of the substrate 131, and the color filter 121 is formed on the other side of the substrate 131. After the integrated structure is formed, it is positioned and assembled with the photosensitive element 110, and the assembled photosensitive assembly is packaged.

In some embodiments, the photosensitive element, the at least one filter element, and the metasurface light-guiding element are integrated on the same substrate. For example, the structure of the photosensitive element is formed on the substrate. The structure is then used as a production base. The at least one filter element and the metasurface light-guiding element are sequentially fabricated on the production base to form an integrated structure, and the integrated structure is then packaged.

Compared with assembling after being manufactured separately, the above design not only makes the manufacturing process simpler, but also reduces or even avoids engineering tolerance errors caused by assembling operations. In addition, because certain components share the same substrate, the number of substrates may be reduced to effectively reduce a thickness of the imaging system, which makes it easier to achieve a thinner and lighter design of the imaging system.

In some embodiments, as shown in FIG. 4, the photosensitive assembly 100 may further include an optical focus element 160 located between the photosensitive element 110 and the at least one filter element 120. The specific structure type of the optical focus element 160 is not limited. For example, the optical focus element may be a metasurface element, a diffraction element, or a micro-lens element. The optical focus element 160 makes light converge and then enter the photosensitive element 110, which is beneficial to improve photosensitivity of the photosensitive element 110, and further improves the imaging quality. The optical focus element 160 may be integrated with one or more adjacent elements to form an integrated element.

As shown in FIG. 5, the present disclosure further provides an imaging system 200. The imaging system 200 includes the photosensitive assembly 100 of any one of the above-described embodiments. The imaging system provided by the present disclosure has higher light transmission efficiency and higher SNR, such that the imaging quality is higher. It should be understood that, in addition to the photosensitive assembly 100, the imaging system 200 may also include other optical elements (not shown in the figure) according to optical design requirements. For example, the imaging system 200 may include one or more traditional lenses, half mirrors, or metasurface elements. The present disclosure is not limited thereto.

The present disclosure also provides an optical electronic device. The optical electronic device includes the imaging system of the above-described embodiment. The optical electronic device includes but is not limited to cameras of mobile terminals, lenses of virtual reality devices, or augmented reality devices, etc. The imaging system of the optical electronic device has high imaging quality.

The specification provides many different embodiments or examples that may be used to implement the present disclosure. It should be understood that these different embodiments or examples are purely exemplary and are not intended to limit the protection scope of the present disclosure in any way. Those skilled in the art can conceive of various changes or substitutions on the basis of the disclosed contents in the specification of the present disclosure, and these changes or substitutions should be covered within the protection scope of the present disclosure. Therefore, the protection scope of the present disclosure should be defined by the appended claims.

What is claimed is:

1. A photosensitive assembly comprising:
a photosensitive element including a plurality of pixels arranged in an array, the plurality of pixels including two groups of pixels configured to respectively sense incident light of different properties, including incident light of different wavelength bands or incident light of different polarization directions;
a filter element including at least one of:
a color filter, including a plurality of color filter units arranged in one-to-one correspondence with the plurality of pixels, the plurality of color filter units including two groups of color filter units corresponding to the two groups of pixels, respectively, and each of the two groups of color filter units having a light-passing wavelength band corresponding to a wavelength band sensed by a corresponding one of the two groups of pixels,
a polarization filter, or
an aperture, including a plurality of light-transmission regions arranged in one-to-one correspondence with the plurality of pixels; and
a metasurface light-guiding element configured to guide the incident light of different properties to respective ones of the two groups of pixels.

2. The photosensitive assembly of claim 1, wherein:
the filter element includes the color filter, and the color filter includes a metasurface element, a diffraction grating element, a dyed filter, or a coated grating filter.

3. The photosensitive assembly of claim 1, wherein:
the filter element includes the polarization filter, and the polarization filter includes a metasurface element, a diffraction grating element, a metal linear polarizer, or a coated grating filter.

4. The photosensitive assembly of claim 1, wherein:
the filter element includes the color filter and the polarization filter; and
the polarization filter is located between the color filter and the metasurface light-guiding element, or is located between the color filter and the photosensitive element, or is integrated with the color filter.

5. The photosensitive assembly of claim 1, wherein:
the filter element includes the color filter and the aperture; and
the aperture is located between the color filter and the metasurface light-guiding element, or is located between the color filter and the photosensitive element, or is integrated with the color filter.

6. The photosensitive assembly of claim 1, further comprising:
an optical focus element disposed between the photosensitive element and the filter element.

7. The photosensitive assembly of claim 6, wherein:
the optical focus element includes a metasurface element, a diffraction element, or a micro-lens element.

8. The photosensitive assembly of claim 1, wherein:
the filter element and the metasurface light-guiding element are integrated on a same substrate.

9. The photosensitive assembly of claim 1, wherein:
the photosensitive element, the filter element, and the metasurface light-guiding element are integrated on a same substrate.

10. An imaging system comprising:
a photosensitive assembly including:
a photosensitive element including a plurality of pixels arranged in an array, the plurality of pixels including two groups of pixels configured to respectively sense incident light of different properties, including incident light of different wavelength bands or incident light of different polarization directions;
a filter element including at least one of:
a color filter, including a plurality of color filter units arranged in one-to-one correspondence with the plurality of pixels, the plurality of color filter units including two groups of color filter units corresponding to the two groups of pixels, respectively, and each of the two groups of color filter units having a light-passing wavelength band corresponding to a wavelength band sensed by a corresponding one of the two groups of pixels,
a polarization filter, or
an aperture, including a plurality of light-transmission regions arranged in one-to-one correspondence with the plurality of pixels; and
a metasurface light-guiding element configured to guide the incident light of different properties to respective ones of the two groups of pixels.

11. The imaging system of claim 10, wherein:
the filter element includes the color filter, and the color filter includes a metasurface element, a diffraction grating element, a dyed filter, or a coated grating filter.

12. The imaging system of claim 10, wherein:
the filter element includes the polarization filter, and the polarization filter includes a metasurface element, a diffraction grating element, a metal linear polarizer, or a coated grating filter.

13. The imaging system of claim 10, wherein:
the filter element includes the color filter and the polarization filter; and
the polarization filter is located between the color filter and the metasurface light-guiding element, or is located between the color filter and the photosensitive element, or is integrated with the color filter.

14. The imaging system of claim 10, wherein:
the filter element includes the color filter and the aperture; and
the aperture is located between the color filter and the metasurface light-guiding element, or is located between the color filter and the photosensitive element, or is integrated with the color filter.

15. The imaging system of claim 10, wherein:
the photosensitive assembly further includes an optical focus element disposed between the photosensitive element and the filter element.

16. The imaging system of claim 15, wherein:
the optical focus element includes a metasurface element, a diffraction element, or a micro-lens element.

17. The imaging system of claim 10, wherein:
the filter element and the metasurface light-guiding element are integrated on a same substrate.

18. The imaging system of claim 10, wherein:
the photosensitive element, the filter element, and the metasurface light-guiding element are integrated on a same substrate.

19. An optical electronic device comprising an imaging system, wherein the imaging system includes a photosensitive assembly and the photosensitive assembly includes:
a photosensitive element including a plurality of pixels arranged in an array, the plurality of pixels including two groups of pixels configured to respectively sense incident light of different properties, including incident light of different wavelength bands or incident light of different polarization directions;
a filter element including at least one of:
a color filter, including a plurality of color filter units arranged in one-to-one correspondence with the plurality of pixels, the plurality of color filter units including two groups of color filter units corresponding to the two groups of pixels, respectively, and each of the two groups of color filter units having a light-passing wavelength band corresponding to a wavelength band sensed by a corresponding one of the two groups of pixels,
a polarization filter, or
an aperture, including a plurality of light-transmission regions arranged in one-to-one correspondence with the plurality of pixels; and
a metasurface light-guiding element configured to guide the incident light of different properties to respective ones of the two groups of pixels.

20. The optical electronic device of claim 19, wherein:
the filter element includes the color filter, and the color filter includes a metasurface element, a diffraction grating element, a dyed filter, or a coated grating filter.
